(19) United States
(12) Patent Application Publication
(10) Pub. No.: US 2011/0049701 A1
(43) Pub. Date: Mar. 3, 2011

(54) SEMICONDUCTOR DEVICE AND METHOD OF MANUFACTURING THE SAME

(75) Inventor: Yuichi MIYAGAWA, Kanagawa (JP)

(73) Assignee: RENESAS ELECTRONICS CORPORATION, Kawasaki-shi (JP)

(21) Appl. No.: 12/873,839

(22) Filed: Sep. 1, 2010

(30) Foreign Application Priority Data
Sep. 2, 2009 (JP) 2009-203145

(51) Int. Cl. H01L 23/34; H01L 21/50

(52) U.S. Cl. 257/712; 438/122; 257/E21.499; 257/E23.08; 257/787

(57) ABSTRACT

The semiconductor device includes a substrate; a semiconductor chip mounted over the substrate; resin encapsulating the semiconductor chip; and a heat dissipation material that is arranged over the semiconductor chip and in contact with the resin, wherein the resin includes a first resin region made of a first resin composition, a second resin region made of a second resin composition, and a mixed layer that is formed between the first and second resin regions and obtained by mixing the first resin composition and the second resin composition.

This application is based on Japanese patent application No. 2009-203145, the content of which is incorporated hereinto by reference.

### BACKGROUND

1. Technical Field

The present invention relates to a semiconductor device and a method of manufacturing the same, and particularly, to a semiconductor device including a heat dissipation material and a method of manufacturing the same.

2. Related Art

There are known techniques of forming a semiconductor package by mounting the semiconductor element on the substrate and then encapsulating the semiconductor element using encapsulation resin. In addition, as the semiconductor element progresses to have a high speed, the heat generated from the semiconductor element becomes problematic. For this reason, a heat dissipation material such as a heat dissipation plate for discharging the heat generated from the semiconductor element has been provided. For example, the heat dissipation plate is disposed over the semiconductor element within the semiconductor package to make contact with the encapsulation resin.

In the related art, the semiconductor package has been encapsulated using a single resin composition. However, it is preferable that a material having high insulation properties is used in a portion adjoining a terminal for electrically connecting the semiconductor element and the substrate in order to improve the electrical properties of the semiconductor device. Meanwhile, it is preferable that a material having a high thermal conductivity such as a metal material is used considering the heat dissipation capability. In addition, even when the heat dissipation material is made of a metal material having a high thermal conductivity such as copper, is necessary to improve adherence between such a material and the encapsulation resin. Furthermore, in a case where the semiconductor element is encapsulated by the encapsulation resin when a bonding wire exists, it is necessary to prevent the wire from flowing and falling down in the resin. Moreover, it is necessary to control a warping behavior of the semiconductor package after the encapsulation. When a single resin composition is used, it is difficult to optimize the resin material to simultaneously satisfy such necessities. Therefore, since a plurality of resin materials are to be prepared or developed in order to achieve optimal characteristics, cost increases, and productivity decreases.

Japanese Laid-Open Patent Publication No. H08-162573 describes a semiconductor device which contains a semiconductor element bonded, while placing an adhesive layer in between, to a substrate having a circuit preliminarily formed thereon, and encapsulated by a cured resin layer having a layered structure composed of an inner cured resin layer and an outer cured resin layer. Filler content of the inner cured resin layer herein is set smaller than that of the outer cured resin layer. The publication described that, by virtue of this configuration, the semiconductor device which is successfully suppressed in the flowing of wires and reduced in the warping may be provided. The inner cured resin layer and the outer cured resin layer herein are formed by transfer molding.

Japanese Laid-open Patent Publication No. 08-279576 discloses a configuration including an insulation resin layer which covers a connection portion for electrically connecting a substrate-side connection portion formed at a face for mounting the substrate where the semiconductor element is mounted and an element-side connection portion of the semiconductor element, and a low-melting-point metal layer which covers the semiconductor element and the insulation resin layer and is made of a low-melting-point metal that melts at a temperature equal to or lower than the heat-resistant temperature of the semiconductor element, wherein a metal powder layer as a wettability improvement layer for the melted low-melting-point metal is formed on a surface of the insulation resin layer making contact with the low-melting-point metal layer. This document describes that alloy used in a brazing filler metal, particularly, solder alloy can be preferably used as a low-melting-point metal.

In addition, this document also discloses that the metal powder layer may be obtained by using a metal powder having a higher melting point than that of the low-melting-point metal forming the low-melting-point metal layer, such as tungsten (W), molybdenum (Mo), silver (Ag), or copper (Cu), and a single material or a mixture of two or more species of those materials may be used as the metal powder.

### SUMMARY

The technique described in Japanese Laid-Open Patent Publication No. H08-162573, however, produces a boundary line between the inner cured resin layer and the outer cured resin layer, both of which being formed by transfer molding. Further, the adhesion between the layers tends to be inhibited and consequently to cause separation between the layers to thereby degrade the quality of the semiconductor device, due to existence of a mold releasing agent and oil components on the surface of the inner cured resin layer.

Similarly, in the technique disclosed in Japanese Laid-open Patent Publication No. 08-279576, while a metal powder layer is formed as a wettability improvement layer, it is separately formed from the insulation resin layer and the low-melting-point metal layer. Therefore, interlayer adherence may decrease, layer separation may occur, or quality may be degraded. In addition, in the technique disclosed in Japanese Laid-open Patent Publication No. 08-279576, since the low-melting-point layer does not contain a resin material, it is difficult to obtain an effect of controlling the warping behavior of the semiconductor package after the encapsulation.

In one embodiment, there is provided a semiconductor device including:

a substrate;

a semiconductor element mounted over the substrate;

resin (encapsulation resin) encapsulating the semiconductor element; and

a heat dissipation material that is arranged over the semiconductor element and in contact with the resin,

wherein the resin includes a first resin region composed of a first resin composition, a second resin region composed of a second resin composition, and a mixed layer that is formed between the first resin region and the second resin region obtained by mixing the first resin composition and the second resin composition.

In another embodiment, there is provided a method of manufacturing a semiconductor device including:

encapsulating a semiconductor element mounted over a substrate using resin; and

arranging a heat dissipation material being in contact with the resin over the semiconductor element,

wherein in the encapsulating the semiconductor element, the encapsulation is allowed to proceed using a first resin composition and a second resin composition so that the resin contains a first resin region composed of the first resin composition, a second resin region composed of the second resin composition, and a mixed layer formed between the first resin region and the second resin region so as to have the first resin composition and the second resin composition mixed therein.

With the above structure, it is possible to encapsulate the semiconductor element (semiconductor chip, for example) using the first resin composition and the second resin composition selected depending on the purpose, improve adherence between the first and second resin regions, and prevent separation therebetween. For example, in the case where the first resin composition is disposed in a portion adjoining the terminal for electrically connecting the semiconductor element and the substrate, it is possible to improve the electrical properties of the semiconductor device by configuring the first resin composition using resin having high insulation properties that does not contain a conductive material. In addition, at the same time, it is possible to improve the heat dissipation properties of the semiconductor device by configuring the second resin composition using resin having a high thermal conductivity. As a result, it is possible to obtain a semiconductor device having high productivity and high reliability.

In addition, any combination of the aforementioned elements or any representation of the present invention switching between the method and the apparatus is effectively employed as an aspect of the present invention.

According to the present invention, it is possible to appropriately control the heat dissipation properties and improve quality of the semiconductor device including the resin.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating an exemplary configuration of a semiconductor device according to an embodiment of the present invention;

FIG. 2 is a plan view illustrating an exemplary configuration of a semiconductor device according to an embodiment of the present invention;

FIG. 3 is a cross-sectional view illustrating a sequence of manufacturing the semiconductor device of FIG. 1;

FIGS. 4A and 4B are cross-sectional views illustrating another exemplary sequence of manufacturing a configuration of the semiconductor device according to an embodiment of the present invention;

FIGS. 5A and 5B are cross-sectional views illustrating another exemplary sequence of manufacturing a configuration of the semiconductor device according to an embodiment of the present invention;

FIGS. 6A and 6B are plan views illustrating another exemplary semiconductor device according to an embodiment of the present invention;

FIGS. 7A and 7B are cross-sectional views illustrating another exemplary configuration of the semiconductor device according to an embodiment of the present invention;

FIGS. 8A and 8B are cross-sectional views illustrating another exemplary sequence of manufacturing a configuration of the semiconductor device according to an embodiment of the present invention;

FIG. 9 is a plan view illustrating another exemplary configuration of the semiconductor device according to an embodiment of the present invention;

FIGS. 10A and 10B are cross-sectional views illustrating another exemplary sequence of manufacturing a configuration of the semiconductor device according to an embodiment of the present invention;

FIGS. 11A and 11B are plan views illustrating another exemplary configuration of the semiconductor device according to an embodiment of the present invention;

FIGS. 12A to 12C are plan views illustrating various exemplary heat dissipation plates according to an embodiment of the present invention;

FIGS. 13A and 13B are plan views illustrating various exemplary heat dissipation plates according to an embodiment of the present invention;

FIG. 14 is a plan view illustrating another exemplary configuration of the semiconductor device according to an embodiment of the present invention;

FIGS. 15A and 15B are cross-sectional views illustrating another exemplary sequence of manufacturing a configuration of the semiconductor device according to an embodiment of the present invention;

FIGS. 16A and 16B are cross-sectional views illustrating another exemplary sequence of manufacturing a configuration of the semiconductor device according to an embodiment of the present invention; and

FIGS. 17A to 17D are process cross-sectional views illustrating a sequence of manufacturing the semiconductor device using a compression molding apparatus according to an embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposes.

Hereinafter, embodiments of the present invention will be descried with reference to the accompanying drawings. Throughout all of the drawings, like reference numerals denote like elements, and descriptions thereof will not be repeated.

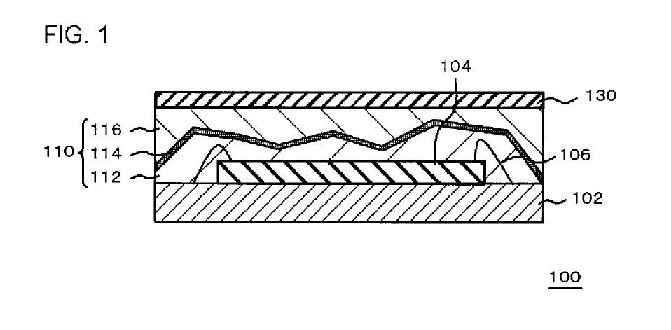

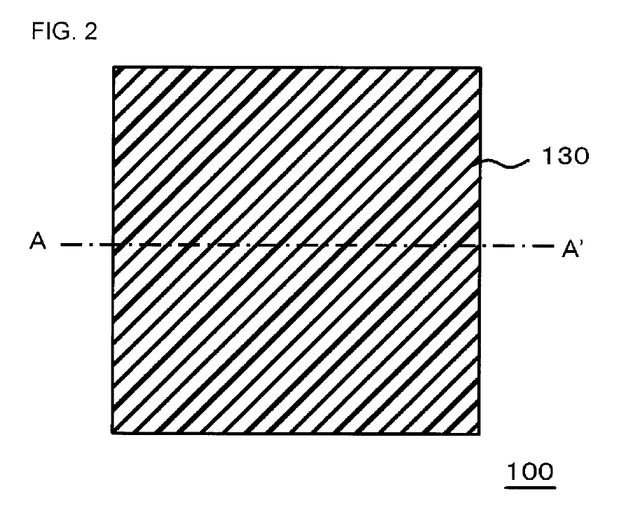

FIG. 1 is a cross-sectional view illustrating an exemplary semiconductor device 100 according an embodiment of the present invention. FIG. 2 is a plan view illustrating a configuration of the semiconductor device 100 according to an embodiment of the present invention. FIG. 1 is a cross-sectional view taken along the line A-A′ of FIG. 2.

The semiconductor device 100 includes a substrate 102, a semiconductor chip 104 (semiconductor element) mounted on the substrate 102, a bonding wire 106 for electrically connecting the substrate 102 to the semiconductor chip 104, an encapsulation resin (resin) 110 for encapsulating the semiconductor chip 104 and the bonding wire 106, and a heat dissipation plate 130 (heat dissipation material) provided to be in contact with the encapsulation resin 110. The substrate 102 may be an interconnect substrate including an interconnect layer. According to the present embodiment, the substrate 102 may be a multi-layered interconnect substrate in which a plurality of interconnect layers are stacked.

According to the present embodiment, the encapsulation resin 110 includes a first resin region 112 including a first resin composition, a second resin region 116 including a second resin composition, and a mixed layer 114 that is formed between the first and second resin regions 112 and 116 and obtained by mixing the first resin composition and the second resin composition. The interface between the first resin region 112 and the mixed layer 114 and the interface between the second resin region 116 and the mixed layer 114 respectively have undulations. Here, “having an undulation” means the interface has a plurality of unevennesses or wavy shape when seen in a cross-sectional view.

In the example shown in FIG. 1, the first resin region 112 is formed on the entire surface of the substrate 102, and the second resin region 116 is formed on the first resin region 112. The mixed layer 114 is formed on the entire surface of the area between the first and second resin regions 112 and 116. The bonding wire 106 and the mainframe of the semiconductor chip 104 are buried by the first resin region 112.

According to the present embodiment, the heat dissipation plate 130 has a plane extending in parallel with an in-plane direction of the substrate 102 over the semiconductor chip 104. Here, “parallel with the in-plane direction of the substrate 102” means a configuration intended to arrange a plane in parallel with the in-plane direction of the substrate 102 and includes “approximately parallel.” In the present example, the heat dissipation plate 130 may be formed to have a flat shape. As shown in FIG. 2, the heat dissipation plate 130 is provided across the entire surface of the semiconductor device 100 when seen in a plan view. In addition, the heat dissipation plate 130 is at least provided to be in contact with the second resin region 116. In the present example, the heat dissipation plate 130 is arranged on the surface of the semiconductor device 100 over the upper face of the second resin region 116.

The heat dissipation plate 130 may be made of a metal material having a higher thermal conductivity than that of the resin composition, such as copper. For example, the heat dissipation plate 130 is made of copper and may include a nickel-plated film on the surface.

Here, a source material of the first resin composition of the first resin region 112 and the second resin composition of the second resin region 116 may contain resin as a base material, a curing agent, and a filler. In addition, the source materials of the first resin composition and the second resin composition may additionally contain a flexibility enhancer, a curing accelerator, latent catalyst, a mold releasing agent, silicone oil, a stress reducing agent, colorant and so forth as source materials. The filler may be made of, for example, silica, alumina, or the like.

The first resin composition and the second resin composition may differ in fluidity under heating in the process of encapsulation before being cured. The first and the second resin compositions may also differ in curing shrinkage characteristics. In addition, the first resin composition and the second resin composition may have, for example, different glass transition temperatures (Tg). The difference in the glass transition temperature between the first resin composition and the second resin composition may be set to be equal to or larger than, for example, 5° C.

For example, the first resin composition and the second resin composition may also differ in a content (wt %) of the filler relative to a total amount of the resin compositions. By reducing the content (wt %) of the filler, it is possible to increase the fluidity of the resin composition. The difference in the content (wt %) of the filler relative to a total amount of the resin compositions between first resin composition and the second resin composition may be, for example, equal to or larger than 1%.

For example, the first resin composition and the second resin composition may differ in an average particle size of the filler contained therein. By increasing the average particle size of the filler, it is possible to increase the fluidity of the resin composition. The difference in the average particle sizes of the fillers contained in the first resin composition and the second resin composition may be, for example, equal to or larger than 5 μm.

The first resin composition and the second resin composition may also differ, for example, in a species or percentage of the source material. The first resin composition and the second resin composition may have, for example, a different curing agent or a different main material of the resin.

By using a resin composition having a high fluidity, it is possible to prevent the bonding wire 106 from flowing and falling down in the resin. Meanwhile, by using a resin composition having a low fluidity, it is possible to reduce post-curing shrinkage of the resin and make it difficult to generate warping.

According to the present embodiment, the first resin composition of the first resin region 112 for encapsulating the bonding wire 106 may be made of a high insulation material that does not contain a conductive material. As a result, it is possible to allow a terminal such as a bonding wire 106 for electrically connecting the semiconductor chip 104 with the substrate 102 to maintain insulation with other components and improve the electrical properties of the semiconductor device 100. In addition, the first resin composition of the first resin region 112 for encapsulating the bonding wire 106 has a function of improving encapsulating the semiconductor chip 104 or the bonding wire 106. For example, the first resin composition may have a high fluidity. By encapsulating the bonding wire 106 of the semiconductor chip 104 using the first resin composition having a high fluidity, it is possible to prevent the bonding wire 106 from flowing.

According to the present embodiment, the second resin composition of the second resin region 116 may be made of, for example, resin having a high thermal conductivity or capable of effectively dissipating the heat generated in the semiconductor chip 104 or a material capable of providing strong adherence to the heat dissipation plate 130. The second resin composition may contain, for example, a filler made of a material having a high thermal conductivity. Such a filler may be made of, for example, a conductive material such as alumina. It means that the second resin composition may contain a filler made of a material having a relatively high conductivity such as alumina. Furthermore, the second resin composition may contain a tackifier such as a silane coupling agent for improving adherence to the heat dissipation plate 130. Meanwhile, the second resin composition may be made of a material having a lower fluidity than that of the first resin composition.

When the second resin composition contains a filler made of a conductive material, it is possible to improve a heat dissipation capability of the second resin region 116. In addition, if the second resin composition contains a tackifier, it is possible to improve adherence between the second resin region 116 and the heat dissipation plate 130. Furthermore, if the encapsulation resin 110 includes the second resin composition having a low fluidity, it is possible to alleviate warping of the semiconductor device 100.

In addition, as the warping behavior can be controlled by changing a content ratio between the first resin composition and the second resin composition, it is possible to obtain a package structure having a high reliability with little warping in the process of encapsulation or packaging without preparing a plurality of resin compositions. Here, for example, the content ratio between the first resin composition and the second resin composition may be set to 99:1 or more and 1:99 or less, and preferably, 90:10 or more and 10:90 or less. As a result, it is possible to appropriately control the amount of warping of the semiconductor device 100.

In addition, according to the present embodiment, as the mixed layer 114 exists between the first resin region 112 and the second resin region 116, it is possible to improve adherence between the first resin region 112 and the second resin region 116 and prevent separation therebetween. According to the present embodiment, since an interface between the first resin region 112 and the mixed layer 114 and an interface between the second resin region 116 and the mixed layer 114 are not flat but undulated, it is possible to further improve adherence between the first resin region 112 and the mixed layer 114 and between the mixed layer 114 and the second resin region 116.

The film thickness (mold thickness) of the encapsulation resin 110 may be set to, for example, be equal to or larger than 0.10 mm and equal to or smaller than 1.20 mm, but not limited thereto. As a result, it is possible to obtain an optimal package structure.

Next, an exemplary sequence of processing the semiconductor device 100 according to the present embodiment will be described.

According to the present embodiment, a process of manufacturing the semiconductor device 100 includes a process of encapsulating the semiconductor chip 104 mounted on the substrate 102 with encapsulation resin 110 and a process of arranging the heat dissipation plate 130 being in contact with the encapsulation resin 110 on the semiconductor chip 104. The semiconductor device 100 is manufactured in the following encapsulation process. In this process, the first resin region 112 and the second resin region 116 are used to make the mixed layer 114 including the mixture of the first resin region 112 and the second resin region 116 between the first resin region 112 and the second resin region 116 so that the semiconductor device 100 includes the first resin region 112, the mixed layer 114, and the second resin region 116. In other words, according to the present embodiment, the encapsulation resin 110 may be formed by arranging the first resin composition and the second resin composition over the substrate 102 while each of the first resin composition and the second resin composition maintains their shapes on some level and performs a curing process in a single time. As a result, it is possible to remove the mutually mixed area and also allow the mutually mixed area to exist therebetween. By virtue of such a sequence, the interface between the first resin region 112 and the mixed layer 114 and the interface between the second resin region 116 and the mixed layer 114 can be allowed to have undulation or wavy shape. In such a manner, by allowing the interface between the first resin region 112 and the mixed layer 114 and the interface between the second resin region 116 and the mixed layer 114 to have undulation and unevenness, it is possible to improve adherence.

According to the present embodiment, the encapsulation resin 110 of the semiconductor device 100 may be formed, for example, using a compression molding process.

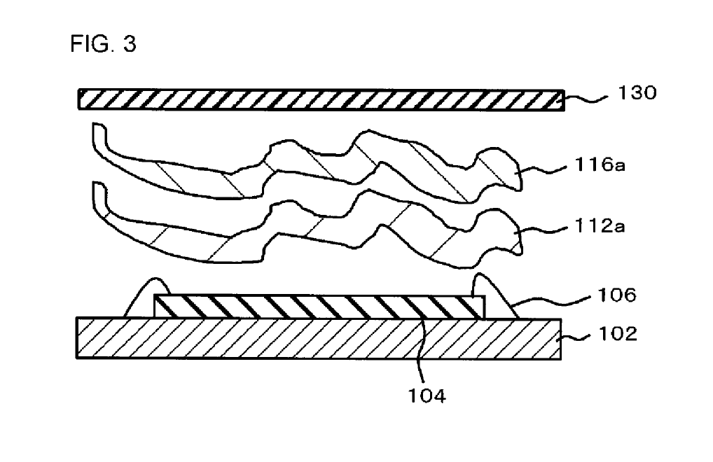

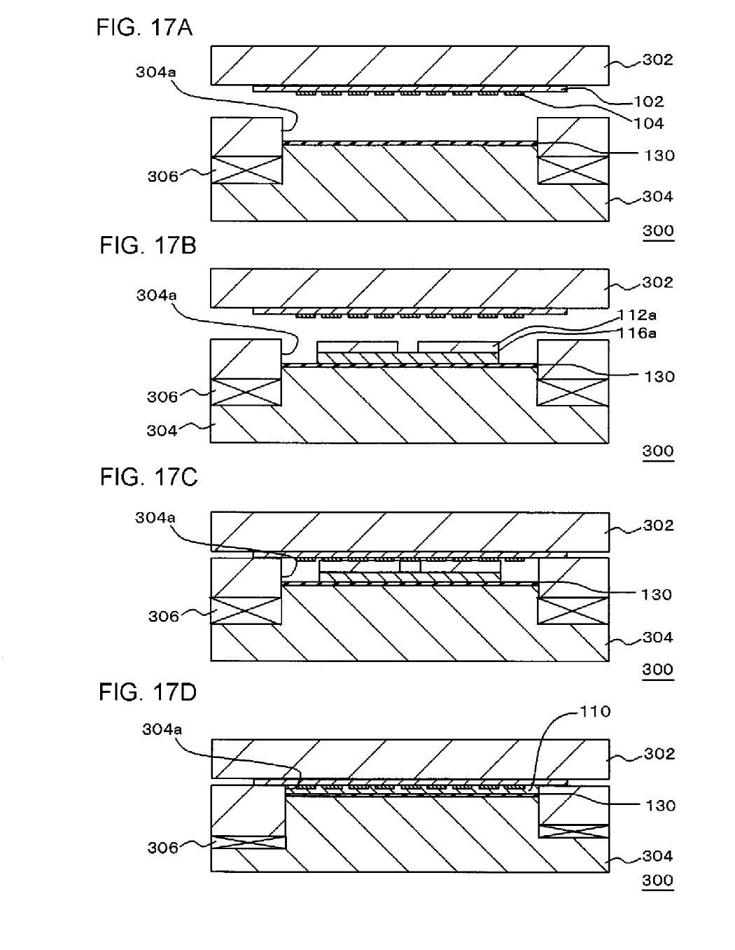

A description will be given with reference to FIGS. 3 and 17A to 17D.

FIG. 3 is a cross-sectional view schematically illustrating a sequence of forming the semiconductor device 100.

Here, the geometry of the resin composition may be arbitrary selected, but may be designed to maintain the shape on some level and avoid a plurality of resin compositions from being mixed in the process of the curing. According to the present embodiment, the resin composition may be a preform body. The preform body may be formed by introducing a granular resin obtained by mixing and mulling source materials of the resin compositions to obtain clayey resin, cooling and fracturing the clayey resin into a standard casing, and heating the granular resin at a low temperature to obtain flat plate-shaped resin (semi-cured).

The compression molding is performed by arranging a first preform body 112a made of the first resin composition and a second preform body 116a made of the second resin composition in this order on the semiconductor chip 104 and the bonding wire 106 of the substrate 102, and further arranging the heat dissipation plate 130 on the second preform body 116a. That is, here, the process of encapsulating the semiconductor chip 104 using the encapsulation resin 110 and the process of arranging the heat dissipation plate 130 on the semiconductor chip 104 are performed at the same time. In addition, although not shown in the drawings, the semiconductor chip 104 may be bonded to the substrate 102 using a die bonding material or the like.

FIGS. 17A to 17D are process cross-sectional views illustrating a sequence of manufacturing the semiconductor device 100 using the compression molding apparatus 300.

The compression molding apparatus 300 includes a lower die 302 and an upper die 304 having a cavity 304a where the resin compositions are arranged. A spring 306 is installed between the outer circumferential wall of the cavity 304a and the mainframe of the upper die 304. In such a configuration of the compression molding apparatus 300, the substrate 102 is installed in the lower die 302 such that the semiconductor chip 104 mounted over the substrate 102 faces the upper die 304. In addition, the heat dissipation plate 130 is disposed within the cavity 304a (as shown in FIG. 17A). Subsequently, the resin composition is set on the heat dissipation plate 130 within the cavity 304a. FIGS. 17A to 17D shows an example in which the heat dissipation plate 130 is disposed within the cavity 304a, and the first preform body 112a made of the first resin composition and the second preform body 116a made of the second resin composition are stacked thereon so as to be set within the cavity 304a (as shown in FIG. 17B). Alternatively, instead of the perform body, the compression molding may be performed using a pre-curing resin composition having an ingot shape which is a tablet of granular resin or granular resin before making the perform body.

In this state, if the compression molding is performed by heating the lower die 302 while pressing it toward the outer circumferential wall of the cavity 304a, the outer circumferential wall of the cavity 304a is moved toward the mainframe of the upper die 304 so that the depth of the cavity 304a becomes shallow. As a result, the first perform body 112a and the second perform body 116a set within in the cavity 304a are melted and cured so as to form the encapsulation resin 110 (as shown in FIGS. 17C and 17D).

Returning to FIG. 3, here, the first preform body 112a and the second preform body 116a may have nearly the same width. As a result, it is possible to obtain the semiconductor device 100 having the configuration as shown in FIG. 1. According to the present embodiment, if the first preform body 112a and the second preform body 116a are simultaneously cured in a stacked state, the mixed layer 114 can be formed between the first and second resin region 112 and 116, and at the same time, the interfaces of the first and second resin regions 112 and 116 with the mixed layer 114 can be made to have corrugated undulation. In addition, since the heat dissipation plate 130 is made to make contact with the second preform body 116a, it is possible to improve adherence between the encapsulation resin 110 and the heat dissipation plate 130.

Next, another example of the semiconductor device 100 of FIGS. 1 to 3 will be described.

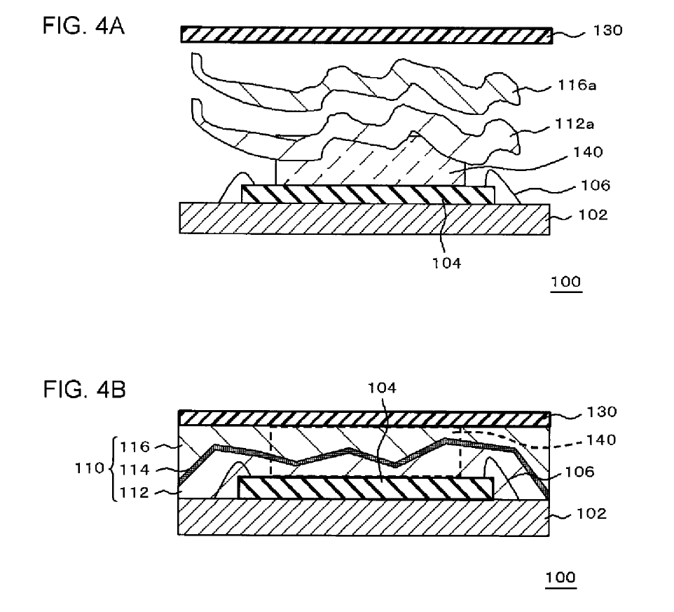

FIGS. 4A and 4B illustrate another exemplary sequence of manufacturing the semiconductor device 100 shown in FIGS. 1 to 3. In this example, the heat dissipation plate 130 may have a configuration as shown in FIG. 3. However, the present example is different from that shown in FIGS. 1 to 3 in that a spacer 140 is provided within encapsulation resin 110 of the semiconductor device 100.

The spacer 140 serves as a pedestal for positioning the heat dissipation plate 130 when the heat dissipation plate 130 is disposed on the semiconductor chip 104. The spacer 140 may be made of, for example, silicon or the like. In this example, the spacer 140 is disposed on the semiconductor chip 104 when the semiconductor chip 104 is encapsulated by the first and second performs 112a and 116a (as shown in FIG. 4A). Thereon, the first preform body 112a, the second preform body 116a, and the heat dissipation plate 130 are stacked in this order, and the semiconductor chip 104 is encapsulated by the encapsulation resin 110 (as shown in FIG. 4B), for example, using a compression molding as described in conjunction with FIGS. 17A to 17D. As a result, it is possible to dispose the heat dissipation plate 130 to have a desired height with respect to the semiconductor chip 104.

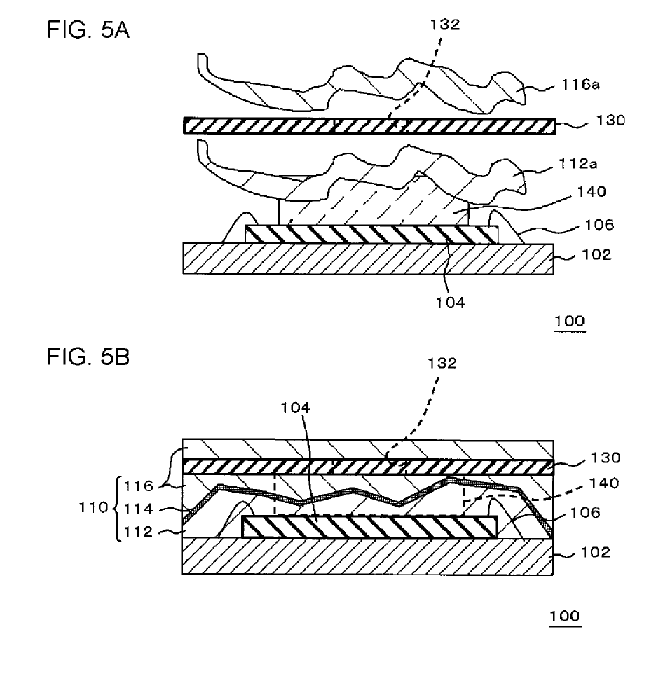

FIGS. 5A and 5B illustrate another exemplary sequence of manufacturing the semiconductor device 100 of FIGS. 4A and 4B.

Here, unlike the example shown in FIGS. 4A and 4B, the heat dissipation plate 130 is not disposed over the upper face of the second resin region 116 but buried within the encapsulation resin 110, and the encapsulation resin 110 is formed on and under the heat dissipation plate 130.

In this example, in the process of encapsulating the semiconductor chip 104 using the encapsulation resin 110, the heat dissipation plate 130 is interposed between the first preform body 112a and the second preform body 116a, and the compression molding is simultaneously performed for both the first preform body 112a and the second preform body 116a. Even in this case, there is disposed the spacer 140 serving as a pedestal for positioning the heat dissipation plate 130 when the heat dissipation plate 130 is disposed on the semiconductor chip 104. The spacer 140 is formed to have a height such that the heat dissipation plate 130 is not located over the upper face of the encapsulation resin 110 but between the encapsulation resins 110. In this example, the spacer 140 is disposed on the semiconductor chip 104 when the semiconductor chip 104 is encapsulated by the first preform body 112a and the second preform body 116a (as shown in FIG. 5A). Thereon, the first preform body 112a, the heat dissipation plate 130, and the second perform 116a are stacked in this order, and the semiconductor chip 140 is encapsulated by the encapsulation resin 110 (as shown in FIG. 5B), for example, using a compression molding as described in conjunction with FIGS. 17A to 17D. As a result, it is possible to dispose the heat dissipation plate 130 to have a desired height with respect to the semiconductor chip 104. Here, the height of the spacer 140 may be set such that most of the heat dissipation plate 130 exists in the second resin region 116 of the encapsulation resin 110.

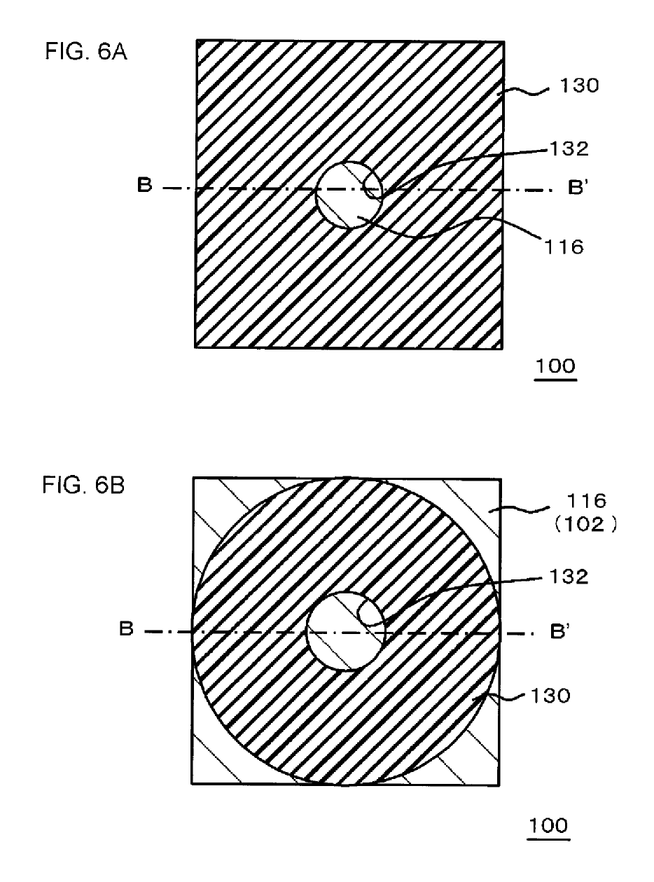

FIGS. 6A and 6B are plan views illustrating a face where the heat dissipation plate 130 of the semiconductor device 100 shown in FIGS. 5A and 5B are formed. Here, while the second resin region 116 formed on the heat dissipation plate 130 is omitted for a descriptive purpose, the second resin region 116 is formed on the heat dissipation plate 130. FIG. 5B shows a cross-section taken along the line B-B′ of FIGS. 6A and 6B.

Here, when seen in a plan view, the heat dissipation plate 130 is formed to be smaller than the area of the semiconductor device 100. As a result, since the resin composition can be moved to upper and lower sides of the heat dissipation plate 130, it is possible to appropriately obtain the semiconductor device 100 having the encapsulation resin 110 formed on and under the heat dissipation plate 130. In this example, the heat dissipation plate 130 is provided with an opening 132. As a result, since the resin composition can move to the upper and lower sides of the heat dissipation plate 130 through the opening 132, it is possible to appropriately obtain the semiconductor device 100 having the encapsulation resin 110 formed on and under the heat dissipation plate 130.

In addition, the heat dissipation plate 130 may have various shapes. For example, as shown in FIG. 6A, the exterior of the heat dissipation plate 130 may have a rectangular shape matching the outer edge of the semiconductor device 100 or a circular shape as shown in FIG. 6B. For example, if the heat dissipation plate 130 has a circular shape, it is possible to appropriately arrange the heat dissipation plate 130 such that the heat dissipation plate 130 does not stick out the substrate 102 even when an arrangement angle of the heat dissipation plate 130 against the substrate 102 is slightly deviated. Although not shown in the drawings, the heat dissipation plate 130 may have an elliptical shape. While the opening 132 is provided in the center of the heat dissipation plate 130 in the example shown in FIGS. 6A and 6B, the opening 132 may be disposed in various other positions as described below. Furthermore, while, in this example, the size of the outer edge of the heat dissipation plate 130 is equal to that of the semiconductor device 100, the size of the outer edge of the heat dissipation plate 130 may be smaller than that of the semiconductor device 100 as described below. In addition, even in the configuration shown in FIGS. 1 to 4A and 4B, the opening 132 may be provided in the heat dissipation plate 130. Furthermore, even in the configuration shown in FIGS. 1 to 4A and 4B, the outer edge of the heat dissipation plate 130 may have various other shapes such as an elliptical shape or a circular shape.

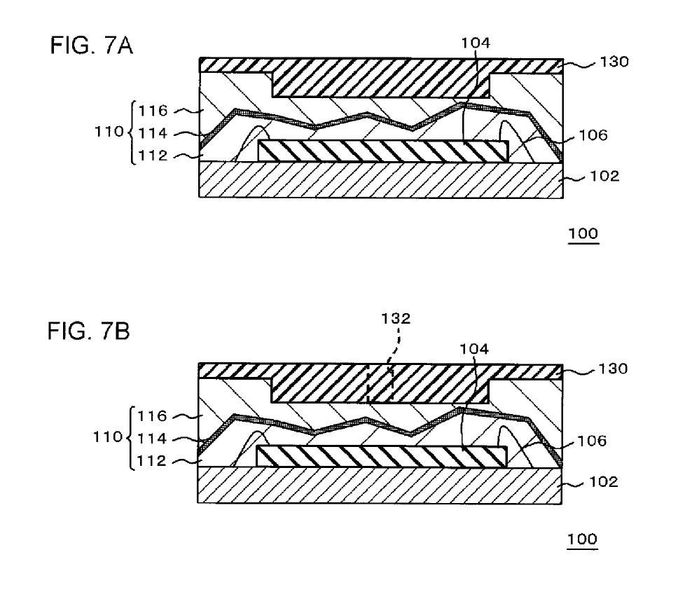

FIGS. 7A and 7B are cross-sectional views illustrating another exemplary semiconductor device 100 according to the present embodiment. Here, when seen in a plan view, only a portion of the heat dissipation plate 130 corresponding to the semiconductor chip 104 is protruded toward the semiconductor chip 104 to be thicker. As a result, it is possible to reduce the distance between the semiconductor chip 104 and the heat dissipation plate 130 and increase a heat dissipation effect of the heat dissipation plate 130. In addition, FIG. 7A illustrates an example where the opening 132 is not provided in the heat dissipation plate 130, and FIG. 7B illustrates an example where the opening 132 is provided in the heat dissipation plate 130. Furthermore, using the heat dissipation plate 130 in this example, the encapsulation resin 110 may be formed over and under the heat dissipation plate 130 as shown in FIGS. 5A and 5B.

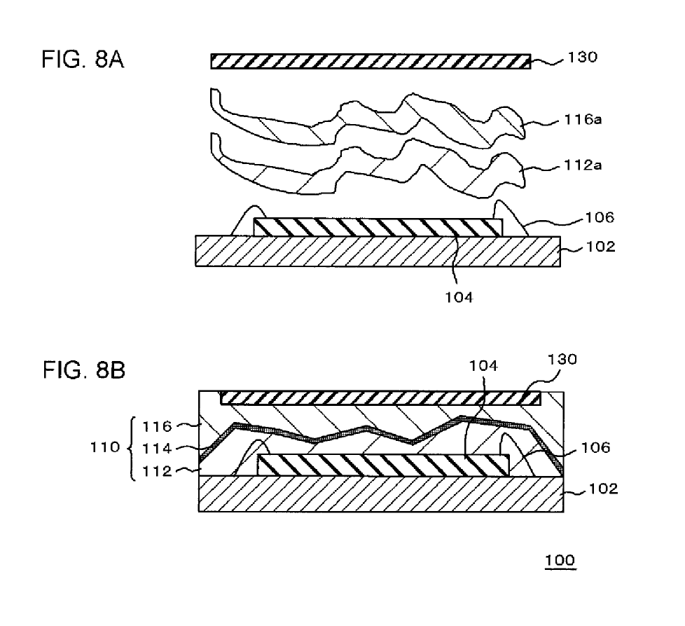

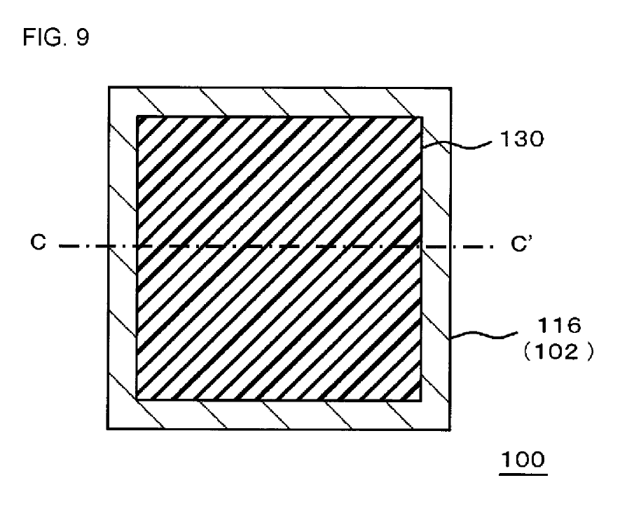

FIGS. 8A, 8B, and 9 illustrate another exemplary sequence of manufacturing the semiconductor device 100 of FIGS. 1 to 3. FIGS. 8A and 8B are cross-sectional views illustrating a sequence of manufacturing the semiconductor device 100, and FIG. 9 is a plan views illustrating the semiconductor device 100. FIG. 8B is a cross-sectional view taken along the line C-C′ of FIG. 9. The present example is different from the configuration of the semiconductor device 100 shown in FIGS. 1 to 3 in that the size of the outer edge of the heat dissipation plate 130 is smaller than that of the semiconductor device 100 when seen in a plan view. Although not shown in the drawings, even in the present example, the heat dissipation plate 130 may be provided with the opening 132.

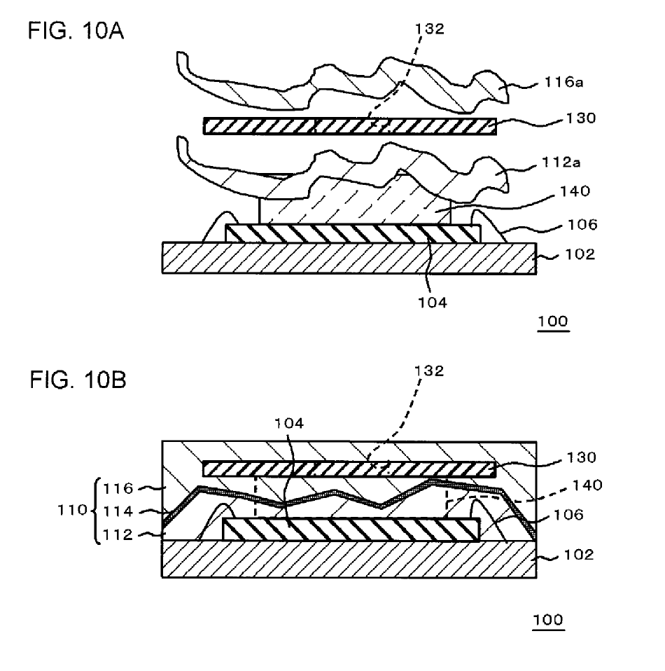

FIGS. 10A and 10B illustrate another exemplary sequence of manufacturing the semiconductor device 100 of FIGS. 8A, 8B, and 9.

Also in the present example, the size of the outer edge of the heat dissipation plate 130 is smaller than that of the semiconductor device 100 when seen in a plan view. In addition, in the present example, as shown in FIGS. 5A and 5B, the encapsulation resin 110 is formed on and under the heat dissipation plate 130, and the spacer 140 is provided between the semiconductor chip 104 and the heat dissipation plate 130. In addition, in the present example, the heat dissipation plate 130 is provided with the opening 132.

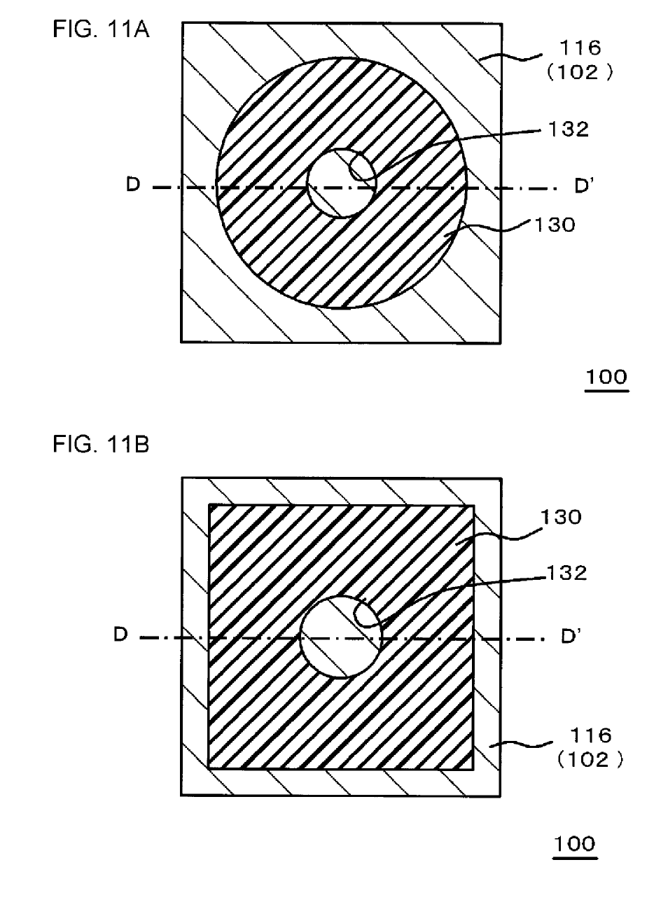

FIGS. 11A and 11B are plan views illustrating a face where the heat dissipation plate 130 of the semiconductor device 100 of FIGS. 10A and 10B is formed. Here, while the second resin region 116 formed on the heat dissipation plate 130 is omitted for a descriptive purpose, the second resin region 116 is formed on the heat dissipation plate 130. FIG. 10B corresponds to a cross-section taken along the line D-D′ of FIGS. 11A and 11B. Also here, the heat dissipation plate 130 may have, for example, a circular shape as shown in FIG. 11A or a rectangular shape as shown in FIG. 11B.

In addition, when the size of the outer edge of the heat dissipation plate 130 is smaller than that of the semiconductor device 100 as in the present example, the opening 132 may not be provided in the heat dissipation plate 130. Even when the opening 132 is not provided, since the heat dissipation plate 130 has a smaller area that that of the semiconductor device 100 when seen in a plan view, the resin composition can move toward upper and lower sides of the heat dissipation plate 130, and it is possible to appropriately obtain the semiconductor device 100 having the encapsulation resin 110 formed on and under the heat dissipation plate 130.

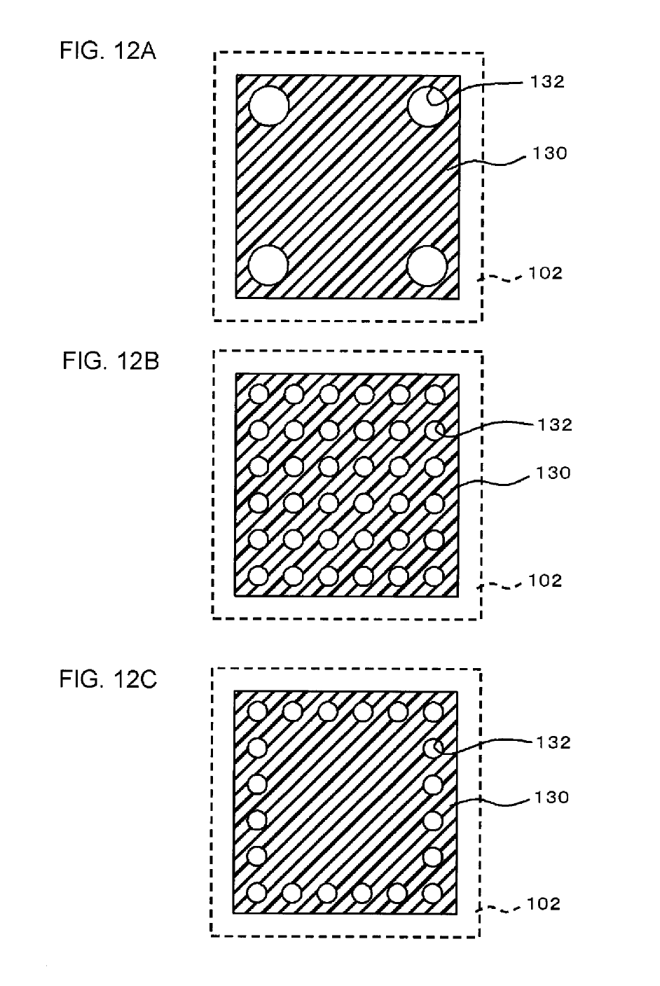

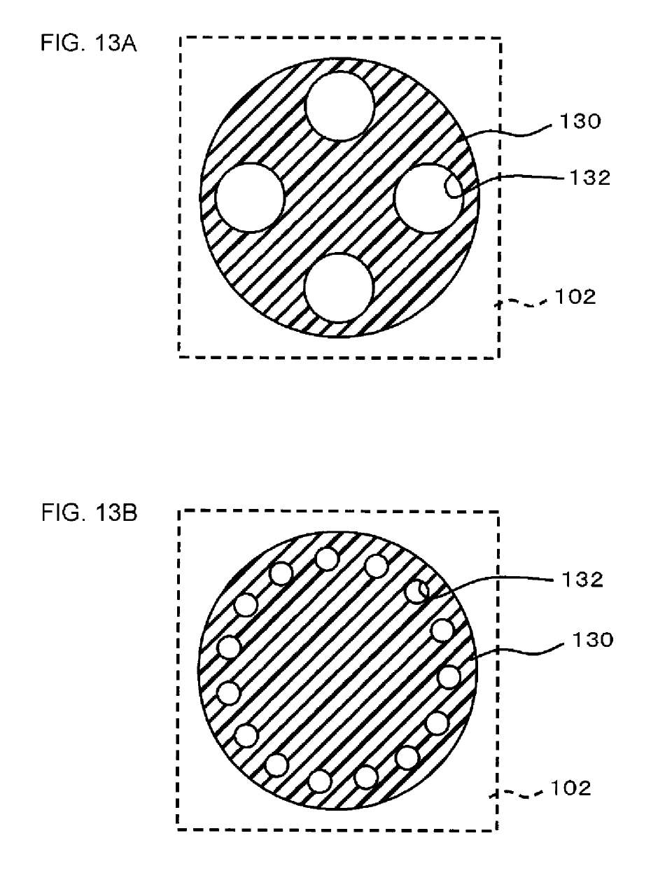

FIGS. 12A to 13B are plan views illustrating various examples of the heat dissipation plate 130. For a descriptive purpose, the shape of the outer edge of the substrate 102 is denoted by a dotted line. While the size of the outer edge of the heat dissipation plate 130 is smaller than that of the semiconductor device 100 in the present example, the present embodiment may be similarly applied even when the size of the outer edge of the heat dissipation plate 130 is equal to that of the semiconductor device 100.

FIGS. 12A to 12C illustrate a case where the heat dissipation plate 130 has a rectangular shape when seen in a plan view. In the configuration of FIG. 12A, openings 132 are provided in each of four corners of the heat dissipation plate 130. In this configuration, it is possible to increase the area of the heat dissipation plate 130 at the portions corresponding to the semiconductor chip 104 when seen in a plan view, and increase the heat dissipation effect by the heat dissipation plate 130.

In the configuration shown in FIG. 12B, a plurality of openings 132 are arranged in a matrix shape on the heat dissipation plate 130. In this configuration, it is possible to allow the encapsulation resin 110 to move over and under the heat dissipation plate 130 through the openings 132, and improve the manufacturing efficiency of the semiconductor device 100 having a configuration that the encapsulation resin 110 is formed over and under the heat dissipation plate 130.

In the configuration shown in FIG. 12C, a plurality of openings 132 are arranged in an outer circumference of the heat dissipation plate 130. In this configuration, it is possible to allow the encapsulation resin 110 to move over and under the heat dissipation plate 130 through the openings 132, and, at the same time, increase the area of the heat dissipation plate 130 at the portions corresponding to the semiconductor chip 104 when seen in a plan view.

FIGS. 13A and 13B illustrate a case where the heat dissipation plate 130 has a circular shape when seen in a plan view. In the configuration of FIG. 13A, the openings 132 are provided at four portions in the outer circumference of the heat dissipation plate 130. In this configuration, it is possible to increase the area of the heat dissipation plate 130 at the portions corresponding to the semiconductor chip 104 when seen in a plan view, and increase the heat dissipation effect by the heat dissipate plate 130.

In addition, in the configuration shown in FIG. 13B, a plurality of openings 132 are arranged in the outer circumference of the heat dissipation plate 130. In this configuration, it is possible to allow the encapsulation resin 110 to move over and under the heat dissipation plate 130 through the openings 132, and, at the same time, increase the area of the heat dissipation plate 130 at the portions corresponding to the semiconductor chip 104 when seen in a plan view.

In addition, a plurality of openings 132 may be arranged in a matrix shape on the entire surface of the heat dissipation plate 130 as shown in FIG. 12B even when the outer edge of the heat dissipation plate 130 has a circular shape.

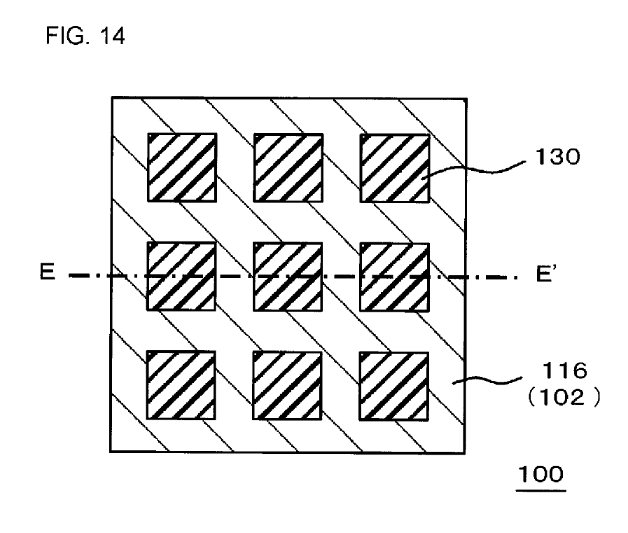

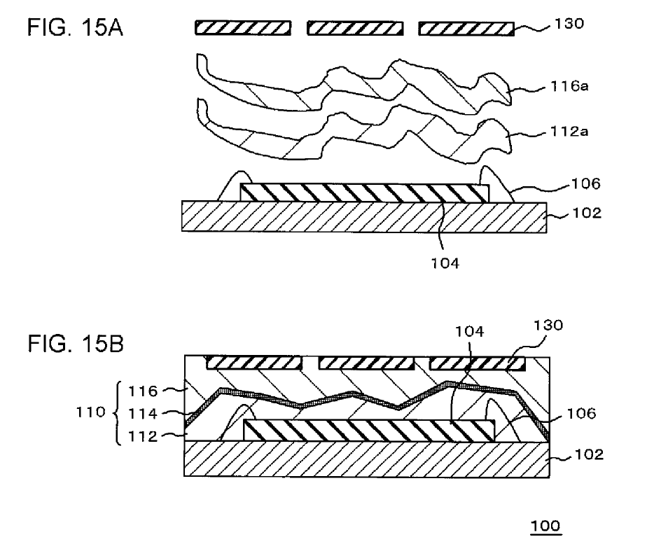

While, in the example shown in FIGS. 1 to 13B, the heat dissipation plate 130 provided in each semiconductor device 100 is configured of a single member, the heat dissipation plate 130 may be configured of a plurality of members. FIGS. 14, 15A, and 15B illustrate the semiconductor device 100 having such a configuration. FIG. 14 is a plan view illustrating the semiconductor device 100, and FIGS. 15A and 15B are cross-sectional views illustrating a sequence of manufacturing the semiconductor device 100. FIG. 15B is a cross-sectional view taken along the line E-E′ of FIG. 14.

Here, the heat dissipation plate 130 may include a plurality of plate-shaped members. The semiconductor device 100 having such a configuration can be obtained by arranging the first preform body 112a and the second preform body 116a on the semiconductor chip 104 as shown in FIGS. 15A and 15B, arranging a plurality of heat dissipation plates 130 on the second preform body 116a (as shown in FIG. 15A), and then, simultaneously performing a compression molding for them (as shown in FIG. 15B).

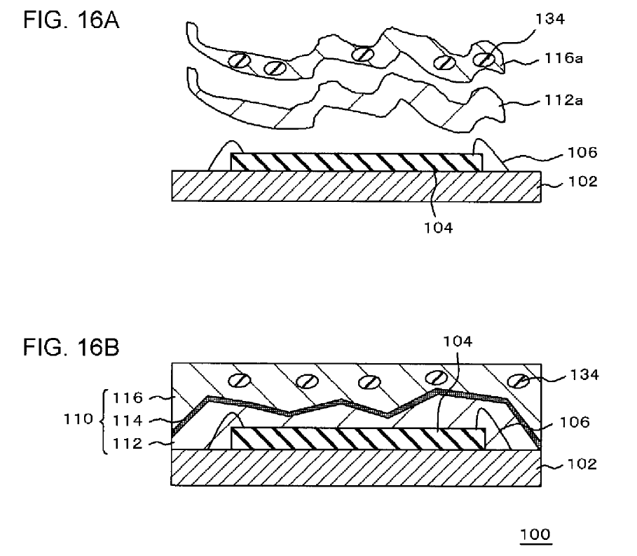

For example, the second resin composition of the second resin region 116 may contain a heat dissipation material made of a metal material having a high thermal conductivity such as copper. FIGS. 16A and 16B illustrate the semiconductor device 100 having such a configuration. Here, the second preform body 116a includes the heat dissipation material 134. The heat dissipation material 134 may be made of a metal material having a high thermal conductivity such as copper. The heat dissipation material 134 may have an elliptical shape or a rectangular shape so as to be uniformly dispersed within the resin. Here, the diameter of the heat dissipation material 134 may be at least equal to or larger than 500 μm. In addition, the heat dissipation material 134 may have a smooth surface without any protrusion on the surface.

By virtue of the aforementioned configuration, it is possible to encapsulate the semiconductor chip using a plurality of resin compositions selected depending on the purpose. At the same time, since the mixed layer is formed between each resin region, it is possible to improve adherence of each resin region and prevent separation therebetween. For example, when the first resin composition is disposed in a portion adjoining the terminal for making electric connection between the semiconductor element and the substrate, it is possible to improve the electrical properties of the semiconductor device by allowing the first resin composition to contain a material having high insulation properties without a conductive material. At the same time, it is possible to improve the heat dissipation properties of the semiconductor device by allowing the second resin composition to contain resin having high thermal conductivity. Consequently, it is possible to obtain a highly reliable package structure having an excellent heat dissipation property and an excellent electrical property without the necessity of preparing or developing a plurality of resin materials in procedure to obtain an optimal characteristic unlike the related art.

For example, in the process of encapsulating the semiconductor chip, if a resin composition having a high fluidity which focuses on the wire flow and another resin composition having a low fluidity which focuses on suppression of the warping behavior are used, both opposing characteristics of the resin compositions can be sufficiently demonstrated. As a result, it is possible to obtain the semiconductor device with a high productivity and a high reliability that may be difficult to realize when a single resin composition is used. In addition, it is possible to improve characteristics such as the warping behavior of the semiconductor device including the encapsulation resin. Furthermore, it is possible to control the warping behavior by changing the ratio of the content of the first resin composition and the second resin composition.

Hereinbefore, while embodiments of the present embodiment have been described with reference to the accompanying drawings, they are illustrated as an example of the present embodiment, and various configurations may be employed.

While the compression molding process has been exemplified in the aforementioned descriptions, a transfer molding process, a potting process, or a printing process may also be employed.

For example, when the semiconductor device 100 shown in FIGS. 16A and 16B is formed through a transfer molding process, a plurality of nozzles may be provided in the mold. Using the mold having such a configuration, after the first resin composition is introduced from a nozzle, the second resin composition is introduced from another nozzle with a time interval. Here, the resin composition introduced later is introduced before the resin material introduced in advance is cured so that both resin compositions are formed through a single curing process. As a result, it is possible to mold the encapsulation resin 110 including the first resin region 112, the mixed layer 114, and the second resin region 116. In addition, the heat dissipation plate 130 may be placed in such as transfer molding process mold in advance, and the semiconductor device including the heat dissipation plate 130 may be formed through the transfer molding process.

While, in the aforementioned embodiments, two kinds of resin compositions such as the first resin composition and the second resin composition are used, the encapsulation resin 110 may include three or more kinds of resin compositions. Even in this case, it is possible to form the mixed layer between each resin composition by simultaneously curing a plurality of resin compositions and obtain the same effect as that obtained in the case where two kinds of resin compositions are used.

In addition, in the encapsulation resin 110, a content ratio or an arrangement between the first and second resin regions 112 and 116 may be variously changed. For example, it is possible to obtain a desired resin region arrangement by arranging the first preform body 112a or the second preform body 116a as the preform body depending on the shape of each resin region included in the targeted encapsulation resin 110.

In addition, while the semiconductor chip 104 is electrically connected to the substrate 102 through the bonding wire 106 in the aforementioned embodiments, the semiconductor chip 104 may be electrically connected to the substrate 102 through a flip-chip connection. When the semiconductor chip 104 is electrically connected to the substrate 102 through the flip-chip connection, underfill resin other than the encapsulation resin 110 may be provided in the connection portion between the flip-chip terminal of the semiconductor chip 104 and the terminal of the substrate 102.

It is apparent that the present invention is not limited to the above embodiment, and may be modified and changed without departing from the scope and spirit of the invention.

What is claimed is:

1. A semiconductor device comprising:
a substrate;
a semiconductor element mounted over said substrate;
resin encapsulating said semiconductor element; and
a heat dissipation material that is arranged over said semiconductor element and in contact with said resin,
wherein said resin includes a first resin region composed of a first resin composition, a second resin region composed of a second resin composition, and a mixed layer that is formed between said first resin region and said second resin region obtained by mixing said first resin composition and said second resin composition.

2. The semiconductor device according to claim 1,
wherein said heat dissipation material is provided to be at least in contact with said second resin region.

3. The semiconductor device according to claim 1,
wherein said heat dissipation material is a heat dissipation plate having a plane extending in parallel with an in-plane direction of said substrate over said semiconductor element.

4. The semiconductor device according to claim 3,
wherein said resin is formed over and under said faces of said heat dissipation plate.

5. The semiconductor device according to claim 3,
wherein said heat dissipation plate has an area smaller than that of said resin when seen in a plan view.

6. The semiconductor device according to claim 3,
wherein said heat dissipation plate is provided with a through-hole.

7. The semiconductor device according to claim 1,
wherein said second resin composition contains a filler made of a conductive material and has a thermal conductivity higher than that of said first resin composition.

8. The semiconductor device according to claim 1,
wherein each of the interface between said first resin region and said mixed layer and the interface between said second resin region and said mixed layer are undulated.

9. The semiconductor device according to claim 1,
wherein said first resin composition and said second resin composition have a different fluidity in the process of encapsulation.

10. The semiconductor device according to claim 1,
wherein said first resin composition and said second resin composition differ in content (weight by %) of a filler relative to the respective total resin composition.

11. The semiconductor device according to claim 1,
wherein said first resin composition and said second resin composition differ in species or ratio of source materials.

12. A method of manufacturing a semiconductor device comprising:
encapsulating a semiconductor element mounted over a substrate using resin; and
arranging a heat dissipation material being in contact with said resin over said semiconductor element,
wherein in said encapsulating the semiconductor element, the encapsulation is allowed to proceed using a first resin composition and a second resin composition so that said resin contains a first resin region composed of said first resin composition, a second resin region composed of said second resin composition, and a mixed layer formed between said first resin region and said second resin region so as to have said first resin composition and said second resin composition mixed therein.

13. The method according to claim 12,
wherein said encapsulating the semiconductor element includes a process of subjecting a first preform body composed of said first resin composition and a second preform body composed of said second resin to composition compression molding at the same time.

14. The method according to claim 12,
wherein said encapsulating the semiconductor element includes a process of subjecting said first resin composition before being cured and said second resin composition before being cured to compression molding at the same time.

15. The method according to claim 12,
wherein said heat dissipation material is a heat dissipation plate having a plane extending in an in-plane direction of said substrate over the semiconductor element,
said encapsulating the semiconductor element using the resin and said arranging the heat dissipation material are simultaneously performed, and
said encapsulating the semiconductor element using the resin includes stacking said first resin composition, said second resin composition, and said heat dissipation plate in this sequence over said semiconductor element over the substrate and simultaneously performing a compression molding for said first resin composition and said second resin composition.

16. The method according to claim 12,
wherein said heat dissipation material is a heat dissipation plate having a plane extending in an in-plane direction of said substrate over said semiconductor element,
said encapsulating the semiconductor element using the resin and said arranging the heat dissipation material are simultaneously performed, and
said encapsulating the semiconductor element using the resin includes interposing said heat dissipation plate between said first resin composition and said second resin composition and simultaneously performing a compression molding for said first resin composition and said second resin composition.

17. The method according to claim 15,
wherein said heat dissipation plate is provided with a through-hole.
